(19) United States
(12) Patent Application Publication
(10) Pub. No.: US 2025/0390403 A1
(43) Pub. Date: Dec. 25, 2025

(54) METHOD AND SYSTEM FOR CONFIGURABLE MEMORY TESTING

(71) Applicant: Quanta Computer Inc., Taoyuan City (TW)

(72) Inventors: Kai-Yu HUANG, Taoyuan City (TW); Yu-Ting LIN, Taoyuan City (TW); Chun-Po MA, Taoyuan City (TW)

(21) Appl. No.: 18/750,353

(22) Filed: Jun. 21, 2024

(51) Int. Cl. G06F 11/22

(52) U.S. Cl. CPC G06F 11/2284

(57) ABSTRACT

A system and method for efficiently testing memory in a computer system is disclosed. A basic input output system (BIOS) is configured to execute an advanced memory test routine in the computer system. A power on self-test routine of the BIOS is run to execute the advanced memory test routine to test a volatile memory. Test result data from the advanced memory test routine is stored in a non-volatile memory.

### TECHNICAL FIELD

The present disclosure relates generally to testing of computer systems. More particularly, aspects of this disclosure relate to a system that allows executing an advanced memory test data from a start up routine and logging of test data in accessible storage.

### BACKGROUND

Servers are employed in large numbers for high demand applications, such as network based systems or data centers. The emergence of cloud computing applications has increased the demand for data centers. Data centers have numerous servers that store data and run applications accessed by remotely connected, computer device users. A typical data center has physical rack structures with attendant power and communication connections. Each rack may hold multiple application servers and storage servers. Each server generally includes hardware components such as processors, memory devices, network interface cards, power supplies, and other specialized hardware. Each of the servers generally includes a baseboard management controller that manages the operation of the server and communicates operational data to a central management station that manages the servers of the rack.

There is a high demand for rapid manufacture of servers based on such demand. Manufacturing requires testing of the server components to ensure the final product meets specifications and is functioning properly. A typical server has a processing unit that may have multiple cores for computing operations that all rely on functional random access memory in the form of dual in line memory modules (DIMMs). Testing the DIMMs is required as they are crucial to the operation of central processing units on the server.

The reliability of memory is crucial for system stability, especially during the boot process. While the standard Intel Memory Reference Code (MRC) algorithm provides a basic memory test of DIMMs, it may not be sufficient to detect all memory issues, including bad or weak memory cells in the DIMMs. To address these shortfalls, memory vendors introduced an Advanced Memory Test (AMT) based on the Intel MRC algorithm. The AMT enhances the memory testing sequence during BIOS boot-up to provide more reliable memory testing.

The Intel AMT identifies and rectifies memory errors using the Converged-Pattern-Generator-Checker (CPGC) algorithm. The Intel AMT is enabled via a setup menu in the BIOS. Once the AMT is enabled in the setup menu, the computer requiring memory testing is rebooted. During start up, the computer enters the AMT procedure to test the full set of DIMMs of the computer. Once any faulty DIMMs are identified, a user can repair DIMMs where the errors are detected. After the repair, the user may rerun the AMT and check the AMT result in the operating system.

However, this process is time-consuming for several reasons. First, the system must be rebooted to modify BIOS settings to activate the AMT. Secondly, the AMT routine as currently programmed detects and scans all memory in the system, and thus, subsequent tests after repair take as long as the initial test. Lastly, testers cannot check the test results during the BIOS Power-On Self-Test (POST) stage and must instead check the test results in the Operating System (OS) using a vendor tool. These factors collectively contribute to an extended overall test and fix time.

In the realm of manufacturing, the time taken for product testing is a critical factor influencing the overall performance of the process. A reduction in verification time can lead to a significant increase in production. When memory errors occur, users often want to perform an in-depth memory test on identified memory modules. However, the existing AMT process involves checking all memory modules during the boot process, which can be time-consuming as opposed to only testing the identified memory modules.

Thus, there is a need for a system that allows test data generated during an AMT to be readily accessible. There is a need for a routine that does not require a reboot of the system in order to perform a memory test. There is another need for a test routine that allows for selective testing of certain memory modules when follow up testing occurs.

### SUMMARY

The term embodiment and like terms, e.g., implementation, configuration, aspect, example, and option, are intended to refer broadly to all of the subject matter of this disclosure and the claims below. Statements containing these terms should be understood not to limit the subject matter described herein or to limit the meaning or scope of the claims below. Embodiments of the present disclosure covered herein are defined by the claims below, not this summary. This summary is a high-level overview of various aspects of the disclosure and introduces some of the concepts that are further described in the Detailed Description section below. This summary is not intended to identify key or essential features of the claimed subject matter. This summary is also not intended to be used in isolation to determine the scope of the claimed subject matter. The subject matter should be understood by reference to appropriate portions of the entire specification of this disclosure, any or all drawings, and each claim.

One disclosed example is a computer system including a basic input output system (BIOS) including an advanced memory test routine. The system includes a volatile memory and a non-volatile memory. A central processing unit is coupled to the memory and the BIOS. The central processing unit executes the advanced memory test routine stored in the BIOS to test the volatile memory. The test result data from the advanced memory test routine is stored in the non-volatile memory.

A further implementation of the example computer system includes a baseboard management controller (BMC) coupled to the non-volatile memory. Another implementation is where the non-volatile memory is a flash memory and where the BMC stores the test result data to a system error log. Another implementation is where the test result data stored on the system error log is accessible via an Intelligent Platform Management Interface (IPMI) command. Another implementation is where the volatile memory includes a plurality of memory modules. The advanced memory test routine includes an option to test a subset of the plurality of memory modules. Another implementation is where the advanced memory test is executed again after a repair of the volatile memory. Another implementation is where the BIOS displays a menu allowing configuration of the advanced memory test routine to execute the option to test a subset of the plurality of memory modules. Another implementation is where the execution of the advanced memory test routine includes repairing any memory modules failing the advanced memory test. Another implementation is where the computer system is a server. Another implementation is where the test result data is stored prior to booting an operating system for the central processing unit.

Another disclosed example is a method of testing volatile memory in a computer system. A basic input output system (BIOS) is configured to execute an advanced memory test routine. A power on self-test routine (POST) of the BIOS is run to execute the advanced memory test routine to test a volatile memory. Test result data from the advanced memory test routine is stored in a non-volatile memory.

Another implementation of the example method is where the non-volatile memory is a flash memory coupled to a baseboard management controller (BMC). The BMC stores the data to a system error log. Another implementation is where the non-volatile memory is a flash memory and where the BMC stores the test result data to a system error log. Another implementation is where the test result data stored on the system error log is accessible via an Intelligent Platform Management Interface (IPMI) command. Another implementation is where the volatile memory includes a plurality of memory modules. The advanced memory test routine includes an option to test a subset of the plurality of memory modules. Another implementation is where the example method includes executing the advanced memory test again after a repair of the volatile memory. Another implementation is where the example method includes displaying a menu from the BIOS allowing configuration of the advanced memory test routine to execute the option to test a subset of the plurality of memory modules. Another implementation is where the example method includes repairing any memory modules failing the advanced memory test via executing the advanced memory test. Another implementation is where the computer system is a server. Another implementation is where the example method includes booting an operating system for the computer system. The test result data is stored prior to booting the operating system.

The above summary is not intended to represent each embodiment or every aspect of the present disclosure. Rather, the foregoing summary merely provides an example of some of the novel aspects and features set forth herein. The above features and advantages, and other features and advantages of the present disclosure, will be readily apparent from the following detailed description of representative embodiments and modes for carrying out the present invention, when taken in connection with the accompanying drawings and the appended claims. Additional aspects of the disclosure will be apparent to those of ordinary skill in the art in view of the detailed description of various embodiments, which is made with reference to the drawings, a brief description of which is provided below.

### BRIEF DESCRIPTION OF THE DRAWINGS

The disclosure, and its advantages and drawings, will be better understood from the following description of representative embodiments together with reference to the accompanying drawings. These drawings depict only representative embodiments, and are therefore not to be considered as limitations on the scope of the various embodiments or claims.

FIG. 1 is a block diagram of a computing system that includes firmware that allows selective memory testing that stores test data in an accessible location;

FIG. 2 is a process diagram showing the example testing process;

FIG. 3A is a screen image of prompts to provide configuration settings for the example memory testing routine;

FIG. 3B is an example DIMM map chart for determining specific DIMMs for testing;

FIG. 4 is a screen image of an example BIOS setup menu to enable the execution of the example memory testing routine;

FIG. 5 is a process diagram of collection of the test results into a system event log;

FIG. 6 is an example log listing from the memory testing process in FIG. 5; and

FIG. 7 is a process diagram for the testing of memory and hardware and software repair in a production setting.

### DETAILED DESCRIPTION

Various embodiments are described with reference to the attached figures, where like reference numerals are used throughout the figures to designate similar or equivalent elements. The figures are not necessarily drawn to scale and are provided merely to illustrate aspects and features of the present disclosure. Numerous specific details, relationships, and methods are set forth to provide a full understanding of certain aspects and features of the present disclosure, although one having ordinary skill in the relevant art will recognize that these aspects and features can be practiced without one or more of the specific details, with other relationships, or with other methods. In some instances, well-known structures or operations are not shown in detail for illustrative purposes. The various embodiments disclosed herein are not necessarily limited by the illustrated ordering of acts or events, as some acts may occur in different orders and/or concurrently with other acts or events. Furthermore, not all illustrated acts or events are necessarily required to implement certain aspects and features of the present disclosure.

For purposes of the present detailed description, unless specifically disclaimed, and where appropriate, the singular includes the plural and vice versa. The word “including” means “including without limitation.” Moreover, words of approximation, such as “about,” “almost,” “substantially,” “approximately,” and the like, can be used herein to mean “at,” “near,” “nearly at,” “within 3-5% of,” “within acceptable manufacturing tolerances of,” or any logical combination thereof. Similarly, terms “vertical” or “horizontal” are intended to additionally include “within 3-5% of” a vertical or horizontal orientation, respectively. Additionally, words of direction, such as “top,” “bottom,” “left,” “right,” “above,” and “below” are intended to relate to the equivalent direction as depicted in a reference illustration; as understood contextually from the object(s) or element(s) being referenced, such as from a commonly used position for the object(s) or element(s); or as otherwise described herein.

The present disclosure relates to a system that provides memory testing through a protocol using BIOS settings to activate the Intel Advanced Memory Test (AMT) routine. The memory test may thus be conducted during the BIOS power on self test (POST) stage. After initial memory testing on the device under test is conducted, potentially faulty memory modules are determined and repaired. The AMT routine may be run again and the example protocol allows testers to select the specific memory modules that were repaired or replaced for testing, rather than requiring all memory modules to be tested on the device under test. This targeted approach significantly reduces the time required to complete the testing process. Furthermore, the example protocol configures the BIOS to send the test results to a non-volatile memory accessible by the Baseboard Management Controller (BMC) of the computer device under test during the BIOS POST stage. A tester can then review or check the results of the memory test in the System Event Log (SEL) of the BMC stored in the non-volatile memory. This eliminates the need to boot into the operating system (OS) to access the test results, thereby reducing the overall verification and fix time.

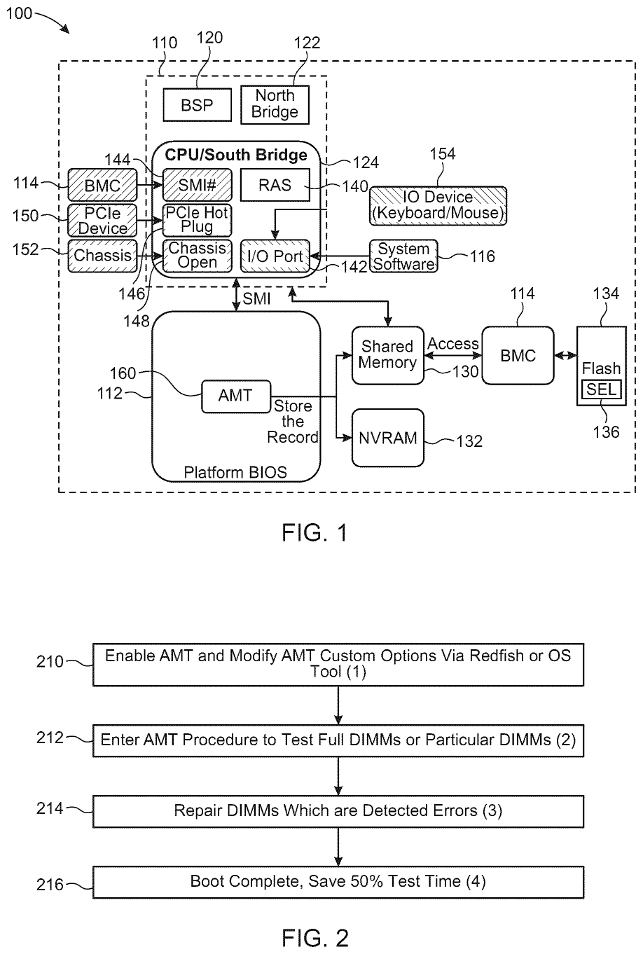

FIG. 1 is a block diagram of a computer system 100 that includes functionality for efficient collection of and accessible storage of AMT data during a manufacturing process that produces the computer system 100. In this example, the computer system 100 is a server, but the principles disclosed herein may be incorporated in any computer system having an operating system having a baseboard management controller and memory modules. The computer system 100 includes a central processing unit (CPU) 110, a platform BIOS 112, a baseboard management controller (BMC) 114, and an operating system (OS) 116. The CPU 110 in this example is a chip set that may include a set of processing cores including a bootstrap processor (BSP) 120 as well as a north bridge chip 122, and a south bridge chip 124.

In this example, the north bridge chip 122 handles memory operations. The south bridge chip 124 performs basic input/output functions for the computer system 100. Another function of both the north bridge and south bridge chips 122 and 124 is to handle different reliability-availability-serviceable (RAS) features. The RAS features are designed to increase reliability, availability and facilitate service of peripheral components in the computer system 100. In this example, RAS features detect device errors in peripheral components such as add-on cards, dual in line memory modules (DIMM) s, and hard disk drives (HDD) s.

The computer system 100 includes a shared volatile memory 130 that may be static random access memory (SRAM) in the form of multiple DIMMs. The manufacturing process includes requirements to test the shared volatile memory 130 on the computer system 100. The computer system 100 also includes a non-volatile memory 132, which may be a flash memory or a similar device. A dedicated BMC non-volatile flash memory 134 stores BMC firmware, as well as a system error log (SEL) 136. In this example, the non-volatile memory 132 may be the same flash memory as the dedicated BMC non-volatile flash memory 134. There may also be separate flash memories for the BMC 114 and the CPU 110. The BMC 114 can access the dedicated BMC non-volatile flash memory 134 to add entries in the SEL 136. An external device such as a management server in a datacenter may communicate via a network interface to the BMC 114 to read entries in the SEL 136. Alternatively, during production process, test equipment may access the BMC 114 to read test data that may be stored in the SEL 136. The BMC 114 can also access data written into the shared volatile memory 130.

In this example, the computer system 100 includes various hardware peripheral devices that access the input/output functions managed by the south bridge chip 124. The hardware peripheral devices in this example include peripheral component interface express (PCIe) devices, dual in line memory modules (DIMM), hard disk drives (HDD) or solid state drives (SDD), universal serial bus (USB) devices, serial peripheral interface (SPI) devices, and system management bus (SMBUS) devices. The PCIe devices may include expansion cards such as NICs (Network Interface Cards), redundant array of inexpensive disks (RAID) cards, field programmable gate array (FPGA) cards, solid state drive (SSD) cards, dual in-line memory devices, and graphic processing unit (GPU) cards. It is to be understood that there may be many such devices, and may include different types of devices from the devices described herein.

The south bridge chip 124 includes reliability-availability-serviceable (RAS) silicon 140 to manage error reports and other RAS functions. The south bridge chip 124 includes a set of input/output ports 142. The south bridge chip 124 also includes an SMI #port 144 that may be coupled to the BMC 114. The south bridge chip 124 also includes PCIe port 146 and a chassis open port 148. In this example, a PCIe device 150 may be coupled to the PCIe port 146 to request interrupts. It is to be understood that there may be multiple PCIe devices represented by the PCIe device 150. The chassis open port 148 may receive sensor interrupts such as a chassis open sensor 152 that requests an interrupt if the chassis of the computer system 100 is detected as open. The interrupts from the ports 144, 146, and 148 are hardware interrupts. Other input/output devices 154 such as a keyboard, mouse, or video device may access the input/output ports 142.

The platform BIOS 112 includes an advanced memory test (AMT) routine 160 that may be executed by the bootstrap processor 120 during the boot up process, if the AMT routine 160 is enabled. In this example, the AMT routine 160 is executed to test the DIMMs of shared volatile memory 130. In this example, during the boot up process, the platform BIOS 112 sends the test results from the AMT routine 160 via an Intelligent Platform Management Interface (IPMI) to the BMC 114 for storage in the SEL 136 in the dedicated BMC non-volatile flash memory 134.

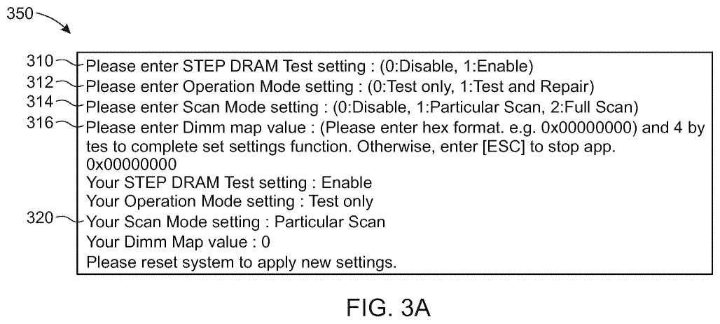

FIG. 2 is a flow diagram of the example process for testing the shared volatile memory 130 of the example computer system 100 in FIG. 1. The AMT routine 160 in FIG. 1 is run during the power on self test (POST) routine. Prior to boot up, the POST routine is configured to enable the AMT routine 160 to be executed (210). The POST routine executes the AMT routine 160 to test the memory modules (DIMMs) constituting the shared volatile memory 130 (212). Once the test results are determined, faulty DIMMs are replaced (214). The test results are passed to the system event log 136 stored in the dedicated BMC non-volatile flash memory 134 accessible by the BMC. After the repair, the AMT routine 160 may be configured to selectively test only the repaired memory modules when the test is rerun (212). After all memory modules are successfully tested, the computer system 100 is booted to the OS 116 (216). In an example Intel Whitley Platform server, tests show that the selective testing of memory modules saves 50% time as compared with running the standard AMT routine on all memory modules after the initial repair of the faulty DIMMs.

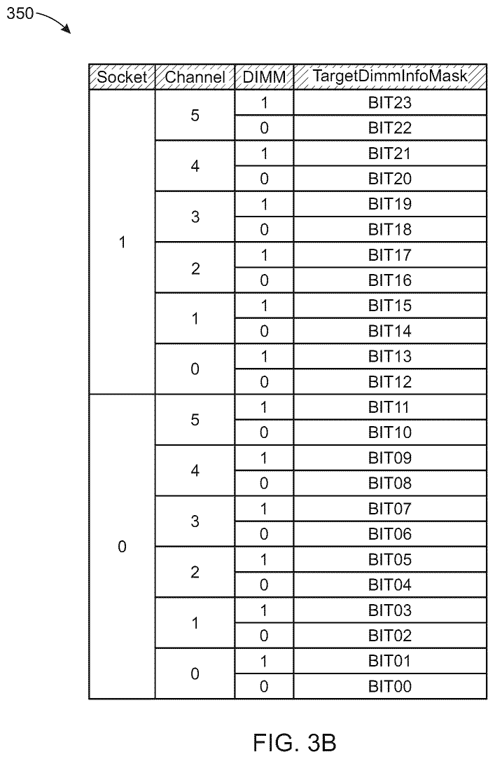

FIG. 3A shows a screen image 300 of an operating system utility for editing a BIOS configuration file that allows the enabling of the AMT routine 160 and the configuration of different settings. In this example, the screen image 300 is a Unified Extensible Firmware Interface (UEFI) shell utility that allows enabling or disabling AMT functions programmatically. The screen image 300 includes a prompt 310 to enable or disable the AMT routine 160 during the POST routine. A prompt 312 allows the option to test only or to test and repair faulty memory modules. A prompt 314 allows a user to select either a particular scan for a set of the DIMMS or a full scan of all the DIMMS. A prompt 316 allows the entering of a DIMM map value when the particular scan option is selected. The user can enter a hex format value to locate the DIMM where an error has occurred.

FIG. 3B is a DIMM map chart 350 that indicates how to convert physical memory to binary format. After calculating a binary value for the DIMM address, it is converted to a hex value. In this example, the DIMM map chart represents a system with 24 DIMMs. Thus, the DIMMS are broken down into two sockets, each of which has six channels. Each of the channels has two DIMMs. The map chart 350 lists 24 BITs each corresponding to an individual DIMM. If the user intends to scan “Socket 0, channel 1, DIMM 0” corresponding to BIT2 and “Socket 1, channel 4, DIMM 1” corresponding to BIT21, then BIT2 and BIT21 are set as 1 and the value of the binary format is 00000000001000000000000000000100. The value in Hex format of the bits will be 0x00200004.

In FIG. 3A, the settings entered in response to the prompts 310, 312, 314 and 316 are summarized in a summary section 320. In this example, the user has enabled the AMT, with testing only. The user has selected a particular scan in this example. The configuration settings entered through the screen image 300 allows a user to enable the AMT with specific settings. Once the settings are entered, the system may be reboot to run the AMT with the configuration settings during the POST routine.

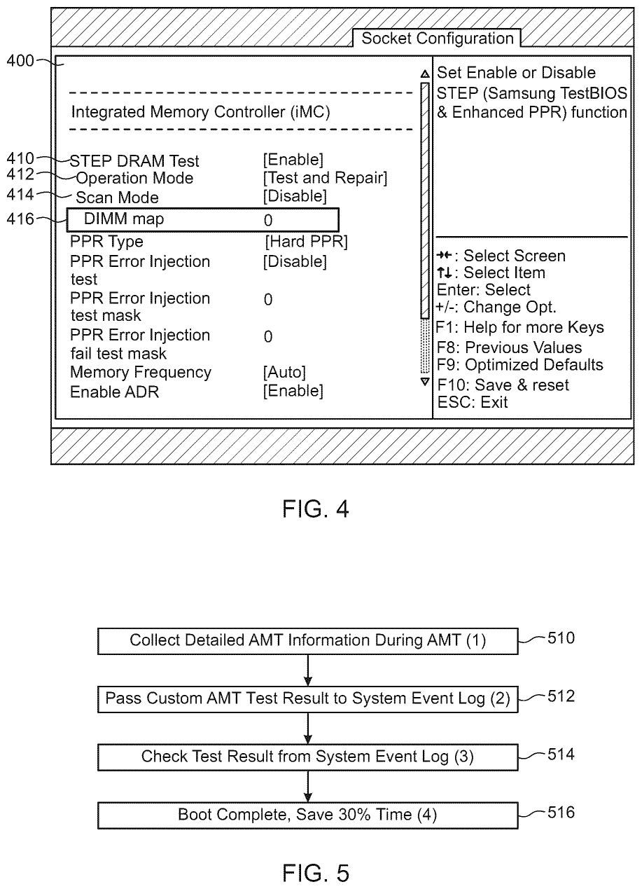

After the reboot is run, the configured AMT is executed. A user may extend the existing options (e.g., “STEP DRAM Test” and “Operation Mode”) to include new parameters such as “Scan Mode” and “DIMM Map.” These options allow selective scanning of memory devices, significantly reducing the overall testing time. FIG. 4 is a screen image of a BIOS configuration menu 400 that may be accessed without running the operating system. The configuration menu 400 allows a user to change settings for a new AMT test that may select only certain memory modules for testing. Thus, the configuration menu 400 includes an enable test selection 410, an operation module selection 412, a scan mode selection 414, and a DIMM map selection 416.

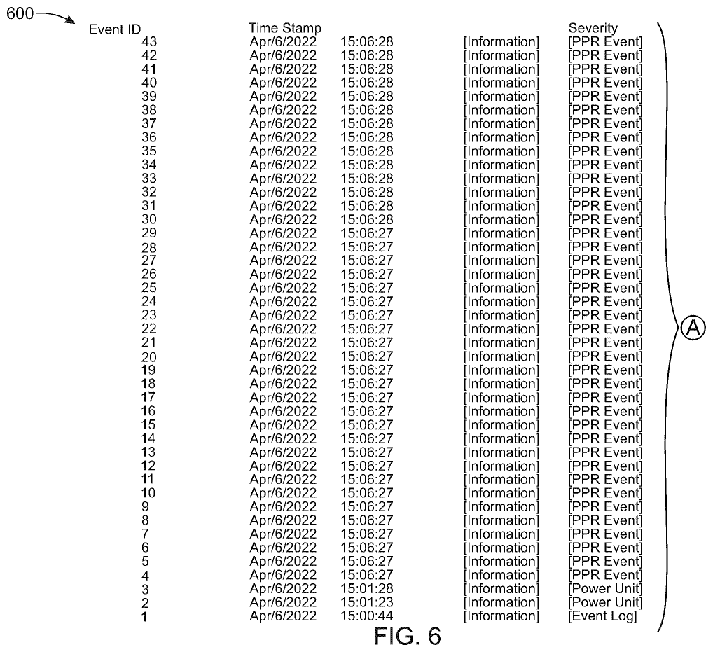

FIG. 5 shows a flow diagram of the testing and data retrieval process for testing the computer system 100 in FIG. 1. As explained in relation to FIG. 2, the AMT is executed during the POST routine and detailed test data is collected (510). The test data is then stored to the system event log 136 in the dedicated BMC non-volatile flash memory 134 (512). In this manner, a reboot does not have to be performed to execute the operating system for accessing the test data. Instead, the data may be retrieved through the BMC 114 in FIG. 1. The data may be used to check test results (514). At this point, either software based (via the AMT) or hardware based (physical replacement of DIMMs) repairs may be attempted. The completion of the boot to the operating system may then occur (514).

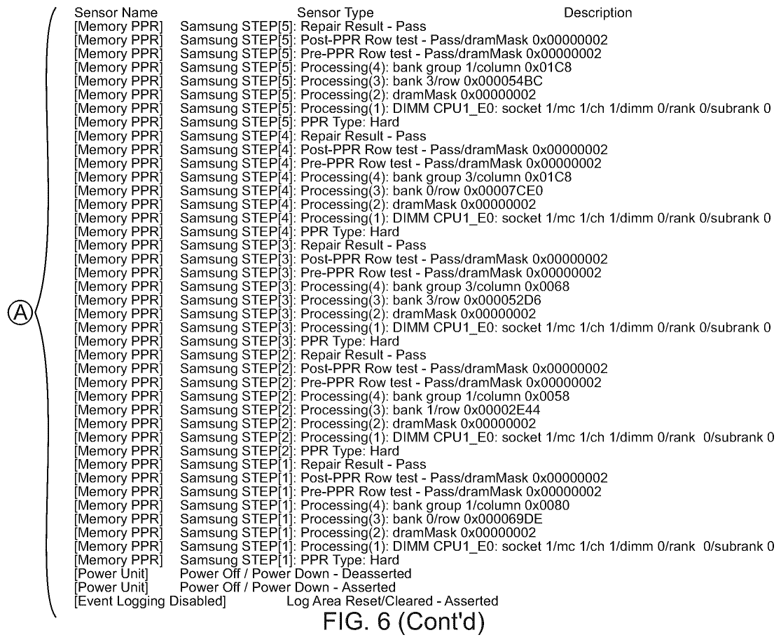

FIG. 6 is an example log listing 600 of test result data from the AMT procedure that may be stored in the SEL 136. The log listing 600 includes a listing of event IDs and corresponding time stamps. The listings include a post package repair (PPR) of testing and repairing DIMMs. In this example, there are two types of PPR: a hard PPR that permanently bypasses faulty DIMMs and a soft PPR that temporarily bypasses faulty DIMMs. The DramMask is a set of patterns used to test DRAM chips for potential faults and defects. In the log listing 600, the string “socket/mc/ch/dimm/rank/subrank/bank_group/bank/row/column” is the address of the basic memory unit. In the address, Socket is the physical connector that houses the CPU on the motherboard. The Memory Controller (MC) is a component that manages the flow of data between the CPU and memory. The Channel (Ch) is a communication pathway between the MC and DIMM. The DIMM is a circuit board that holds memory chips. Rank is a group of memory chips on a DIMM. Subrank is a subdivision of a rank, typically used in high-density DIMM. Bank Group is a group of memory banks that share circuitry for data control. Bank is a memory array that has its own row and column decoders. Row is a horizontal line of memory cells. Column is a vertical line of memory cells.

When data records such as the log listing 600 is stored in the SEL 136 in FIG. 1, a user can use an Intelligent Platform Management Interface (IPMI) command to access the record directly through the BMC 114. The user may analyze the results and decide whether any of the physical DIMMs require replacement. The immediate access to the SEL 136 results in around 30% time savings through bypassing the need to reboot to the operating system as confirmed by testing using a Whitley platform server.

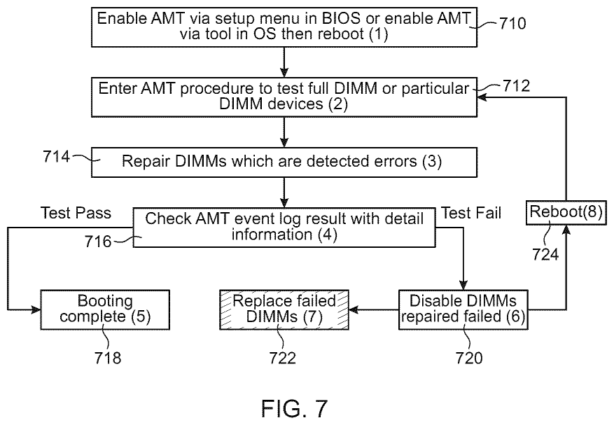

FIG. 7 shows a process of memory testing of the computer system 100 in FIG. 1 that takes advantage of the reduced time from the above referenced principles. The AMT is enabled via either a setup menu in the BIOS or via a tool in the operating system and executed during the POST to detect errors in the memory (710). On the POST, the AMT procedure is executed to test the full set of DIMMs or a particular DIMM or DIMMs according to the DIMM map value in the setup options (712). The routine then repairs all DIMMs where errors are detected (714). During the POST stage, the results of the test may be accessed in the system event log 136 via the BMC 114 and checked to see if the test was successful for all DIMMs (716). If all the DIMMs pass the testing, the boot may continue to the operating system (OS) (718). If the test for any DIMM fails, there exists errors and the system will disable DIMMs where repairs via the AMT failed (720).

The user may replace failed DIMMs identified by the test where attempts to repair such DIMMs have failed (722). The user may then configure the AMT to only check only the repaired DIMMS. The user may then reboot the system (724) and execute the AMT again to only check the replacement DIMMs (712).

The flow diagrams in FIGS. 5 and 7 are representative of example machine readable instructions for executing memory testing in the computer system 100 in FIG. 1 and storing the test data in a BMC accessible storage. In this example, the machine readable instructions comprise an algorithm for execution by: (a) a processor; (b) a controller; and/or (c) one or more other suitable processing device(s). The algorithm may be embodied in software stored on tangible media such as flash memory, CD-ROM, floppy disk, hard drive, digital video (versatile) disk (DVD), or other memory devices. However, persons of ordinary skill in the art will readily appreciate that the entire algorithm and/or parts thereof can alternatively be executed by a device other than a processor and/or embodied in firmware or dedicated hardware in a well-known manner (e.g., it may be implemented by an application specific integrated circuit [ASIC], a programmable logic device [PLD], a field programmable logic device [FPLD], a field programmable gate array [FPGA], discrete logic, etc.). For example, any or all of the components of the interfaces can be implemented by software, hardware, and/or firmware. Also, some or all of the machine readable instructions represented by the flowcharts may be implemented manually. Further, although the example algorithm is described with reference to the flowcharts illustrated in FIGS. 5 and 7, persons of ordinary skill in the art will readily appreciate that many other methods of implementing the example machine readable instructions may alternatively be used. For example, the order of execution of the blocks may be changed, and/or some of the blocks described may be changed, eliminated, or combined.

The example process allows reducing the time spent configuring AMT options and enhances flexibility of the testing. The example routine also allows a user to select a specific protocol and functions that allow users to modify AMT settings directly within the operating system (OS), bypassing the BIOS setup menu. The routine also provides early visibility into memory test results without waiting for the operating system to boot.

The logging of test results directly into the system event log during POST is accomplished through the BIOS sending test results through a common protocol such as IPMI to the BMC. This allows early review as a user can access the SEL during the BIOS POST stage to review or verify memory test outcomes. This eliminates the need to boot into the OS or rely on vendor-specific tools to access the test data.

By leveraging a common protocol such as the IPMI and the SEL, development teams do not have to depend on specialized vendor tools. A tester can design custom log formats tailored to their needs. Enhancing AMT not only improves memory testing accuracy but also streamlines the process. By integrating protocols, enabling selective scanning, and providing real-time test result logs, more efficient and reliable memory testing may occur during system boot.

As used in this application, the terms “component,” “module,” “system,” or the like, generally refer to a computer-related entity, either hardware (e.g., a circuit), a combination of hardware and software, software, or an entity related to an operational machine with one or more specific functionalities. For example, a component may be, but is not limited to being, a process running on a processor (e.g., digital signal processor), a processor, an object, an executable, a thread of execution, a program, and/or a computer. By way of illustration, both an application running on a controller, as well as the controller, can be a component. One or more components may reside within a process and/or thread of execution, and a component may be localized on one computer and/or distributed between two or more computers. Further, a “device” can come in the form of specially designed hardware; generalized hardware made specialized by the execution of software thereon that enables the hardware to perform specific function; software stored on a computer-readable medium; or a combination thereof.

While various embodiments of the present invention have been described above, it should be understood that they have been presented by way of example only, and not limitation. Although the invention has been illustrated and described with respect to one or more implementations, equivalent alterations and modifications will occur or be known to others skilled in the art upon the reading and understanding of this specification and the annexed drawings. In addition, while a particular feature of the invention may have been disclosed with respect to only one of several implementations, such feature may be combined with one or more other features of the other implementations as may be desired and advantageous for any given or particular application. Thus, the breadth and scope of the present invention should not be limited by any of the above described embodiments. Rather, the scope of the invention should be defined in accordance with the following claims and their equivalents.

The terminology used herein is for the purpose of describing particular embodiments only, and is not intended to be limiting of the invention. As used herein, the singular forms “a,” “an,” and “the” are intended to include the plural forms as well, unless the context clearly indicates otherwise. Furthermore, to the extent that the terms “including,” “includes,” “having,” “has,” “with,” or variants thereof, are used in either the detailed description and/or the claims, such terms are intended to be inclusive in a manner similar to the term “comprising.”

Unless otherwise defined, all terms (including technical and scientific terms) used herein have the same meaning as commonly understood by one of ordinary skill in the art. Furthermore, terms, such as those defined in commonly used dictionaries, should be interpreted as having a meaning that is consistent with their meaning in the context of the relevant art, and will not be interpreted in an idealized or overly formal sense unless expressly so defined herein.

1. A computer system comprising:
a basic input output system (BIOS) including an advanced memory test routine;
a volatile memory;
a non-volatile memory;
a baseboard management controller (BMC) coupled to the non-volatile memory; and
a central processing unit coupled to the volatile memory and the BIOS, the central processing unit executing the advanced memory test routine stored in the BIOS to test the volatile memory, and wherein test result data from the advanced memory test routine is transmitted to the BMC and stored in the non-volatile memory by the BMC.

2. (canceled)

3. The computer system of claim 1, wherein the non-volatile memory is a flash memory and wherein the BMC stores the test result data to a system error log.

4. The computer system of claim 3, wherein the test result data stored on the system error log is accessible via an Intelligent Platform Management Interface (IPMI) command.

5. The computer system of claim 1, wherein the volatile memory includes a plurality of memory modules, and wherein the advanced memory test routine includes an option to test a subset of the plurality of memory modules.

6. The computer system of claim 5, wherein the advanced memory test routine is executed again after a replacement of at least one of the plurality of memory modules of the volatile memory, wherein the advanced memory test routine is only executed for the replaced at least one of the plurality of memory modules.

7. The computer system of claim 5, wherein the BIOS displays a menu allowing configuration of the advanced memory test routine to execute the option to test the subset of the plurality of memory modules.

8. The computer system of claim 5, wherein the execution of the advanced memory test routine includes repairing any memory modules failing the advanced memory test.

9. The computer system of claim 1, wherein the computer system is a server.

10. The computer system of claim 1, wherein the test result data is stored prior to booting an operating system for the central processing unit.

11. A method of testing volatile memory in a computer system, the method comprising:
configuring a basic input output system (BIOS) to execute an advanced memory test routine in the computer system;
running a power on self-test routine of the BIOS to execute the advanced memory test routine to test a volatile memory;
transmitting the test result data from the advanced memory test routine to a baseboard management controller (BMC) coupled to a non-volatile memory; and
storing test result data from the advanced memory test routine in a non-volatile memory by the BMC.

12. (canceled)

13. The method of claim 12, wherein the non-volatile memory is a flash memory and wherein the BMC stores the test result data to a system error log.

14. The method of claim 13, wherein the test result data stored on the system error log is accessible via an Intelligent Platform Management Interface (IPMI) command.

15. The method of claim 11, wherein the volatile memory includes a plurality of memory modules, and wherein the advanced memory test routine includes an option to test a subset of the plurality of memory modules.

16. The method of claim 15, further comprising executing the advanced memory test routine again after a replacement or at least one of the plurality of memory modules of the volatile memory, wherein the advanced memory test routine is only executed for the replaced at least one of the plurality of memory modules.

17. The method of claim 15, further comprising displaying a menu from the BIOS allowing configuration of the advanced memory test routine to execute the option to test the subset of the plurality of memory modules.

18. The method of claim 15, further comprising repairing any memory modules of the plurality of memory modules that fail the advanced memory test via executing the advanced memory test.

19. The method of claim 11, wherein the computer system is a server.

20. The method of claim 11, further comprising booting an operating system for the computer system, wherein the test result data is stored prior to booting the operating system.
